(19) United States
(12) Patent Application Publication
(10) Pub. No.: US 2025/0157976 A1
(43) Pub. Date: May 15, 2025

(54) FILM-LIKE ADHESIVE AND METHOD FOR PRODUCING SAME, INTEGRATED DICING/DIE BONDING FILM, AND SEMICONDUCTOR DEVICE AND METHOD FOR PRODUCING SAME

(71) Applicant: Resonac Corporation, Minato-ku, Tokyo (JP)

(72) Inventors: Tomoyo KANEKO, Minato-ku, Tokyo (JP); Kohei TANIGUCHI, Minato-ku, Tokyo (JP); Kazuhiro YAMAMOTO, Minato-ku, Tokyo (JP); Tsuyoshi TAZAWA, Tokyo (JP)

(21) Appl. No.: 18/837,889

(22) PCT Filed: Feb. 14, 2023
(86) PCT No.: PCT/JP2023/005055

§ 371 Date: Aug. 13, 2024

(30) Foreign Application Priority Data
Feb. 16, 2022 (JP) 2022-021992

(51) Int. Cl. H01L 23/00; C09J 5/06; C09J 7/10; C09J 11/04; C09J 163/00; H01L 21/78; H01L 25/065; H10B 80/00

(52) U.S. Cl. CPC H01L 24/29; C09J 5/06; C09J 7/10; C09J 11/04; C09J 163/00; H01L 21/78; H01L 24/27; H01L 24/32; H01L 24/83; H01L 24/94; H01L 25/0657; H10B 80/00; C09J 2203/326; C09J 2301/302; C09J 2301/408; C09J 2301/50; C09J 2463/00; H01L 2224/2731; H01L 2224/27515; H01L 2224/29291; H01L 2224/32145; H01L 2224/32225; H01L 2224/83203; H01L 2224/8385; H01L 2224/94; H01L 2225/0651; H01L 2225/06562; H01L 2924/1438

(57) ABSTRACT

A film-like adhesive contains an epoxy resin, a phenolic resin, an elastomer, and an inorganic filler. A ratio of an epoxy group of the epoxy resin with respect to a hydroxyl group of the phenolic resin is 1.2 or more. A method for producing a film-like adhesive includes applying a varnish of a bonding adhesive composition comprising an epoxy resin, a phenolic resin, an elastomer, an inorganic filler, and a solvent to a support film and removing the solvent from the applied varnish by heating and drying to obtain a film-like adhesive.

### TECHNICAL FIELD

The present disclosure relates to a film-like adhesive and a method for producing the same, an integrated dicing/die bonding film, and a semiconductor device and a method for producing the same.

### BACKGROUND ART

In the field of semiconductors typified by data storage media, integrated circuits (ICs), and the like, in recent years, with the improvement in performance, a semiconductor package has been more densely packaged and more highly integrated. According to this, thinning of a semiconductor wafer is in progress to easily cause problems such as wafer cracking during processing, which may lead to problems of a decrease in yield rate. Therefore, as the thickness of the semiconductor wafer decreases (for example, 50 μm or less), there is an on-going shift from a conventional physical grinding method to a new processing method.

As one of new processing methods, a method has been proposed in recent years in which the inside of a semiconductor wafer on a scheduled cutting line is irradiated with laser light to form a modified region, and then the semiconductor wafer is cut by expanding the outer periphery (for example, Patent Literatures 1 and 2). This method is called stealth dicing. With the development of the new processing method, it becomes necessary to develop a semiconductor material compatible with the processing method. As such a semiconductor material, an integrated dicing/die bonding film having performances of both a dicing film and a die-bonding film has been reported (for example, Patent Literatures 3 and 4).

### CITATION LIST

### Patent Literature

Patent Literature 1: JP 2002-192370 A
Patent Literature 2: JP 2003-338467 A
Patent Literature 3: JP 2015-211080 A
Patent Literature 4: JP 2016-115775 A

### SUMMARY OF INVENTION

### Technical Problem

Incidentally, in a production process of a semiconductor device, a semiconductor element and a support member are bonded to each other with a bonding adhesive layer (bonding adhesive piece) composed of a film-like adhesive interposed therebetween. In processes after bonding, the resultant product may be further exposed to a high temperature, and it is required that the bonding adhesive layer can maintain adhesiveness even at the time of a high-temperature treatment (for example, 150° C. for 6 hours or longer).

Therefore, a main object of the present disclosure is to provide a film-like adhesive capable of sufficiently maintaining adhesiveness even at the time of a high-temperature treatment and a method for producing the same.

### Solution to Problem

The present inventors have conducted intensive studies, and as a result, have found that adhesiveness can be sufficiently maintained even at the time of a high-temperature treatment by adjusting a ratio of an epoxy group of an epoxy resin with respect to a hydroxyl group of a phenolic resin to a specific range in a film-like adhesive containing an epoxy resin, a phenolic resin, an elastomer, and an inorganic filler, thereby completing the present invention.

An aspect of the present disclosure relates to a film-like adhesive. This film-like adhesive contains an epoxy resin, a phenolic resin, an elastomer, and an inorganic filler. A ratio of an epoxy group of the epoxy resin with respect to a hydroxyl group of the phenolic resin is 1.2 or more. When this ratio is 1.2 or more, adhesiveness can be sufficiently maintained even at the time of a high-temperature treatment.

The elastomer may include an elastomer satisfying the following Condition (i) and the following Condition (ii). In the production process of a semiconductor device, in a case where a modified region is formed and divided by stealth dicing, expansion under cooling conditions (hereinafter, referred to as “cooling expansion” in some cases) may be performed. However, when a conventional integrated dicing/die bonding film is applied to cooling expansion, the bonding adhesive layer composed of the film-like adhesive may be not split. When the bonding adhesive layer is not split, problems arise in that the yield rate is deteriorated and the production time efficiency for sorting a non-split produce is deteriorated. When the elastomer includes an elastomer satisfying Condition (i) and Condition (ii), there is a tendency that the ease of splitting by cooling expansion of the film-like adhesive is further improved.
Condition (i): A glass transition temperature is 10° C. or higher.
Condition (ii): A weight average molecular weight is 1000000 or less.

A total content of the epoxy resin and the phenolic resin may be 5 to 25% by mass based on the total amount of the film-like adhesive.

An average particle diameter of the inorganic filler may be 400 nm or less. A content of the inorganic filler may be 18 to 40% by mass based on the total amount of the film-like adhesive.

A thickness of the film-like adhesive may be 25 μm or less.

The film-like adhesive may be used in a production process of a semiconductor device obtained by stacking a plurality of semiconductor elements. In this case, the semiconductor device may be stacked MCP (Multi Chip Package) in which semiconductor elements (semiconductor chips) are stacked in multiple stages, or may be a three-dimensional NAND type memory.

Another aspect of the present disclosure relates to a method for producing a film-like adhesive. This method for producing a film-like adhesive includes applying a varnish of a bonding adhesive composition containing an epoxy resin, a phenolic resin, an elastomer, an inorganic filler, and a solvent to a support film, and removing the solvent from the applied varnish by heating and drying to obtain a film-like adhesive. A ratio of an epoxy group of the epoxy resin with respect to a hydroxyl group of the phenolic resin is 1.2 or more.

Still another aspect of the present disclosure relates to an integrated dicing/die bonding film. This integrated dicing/die bonding film includes a base material layer, a pressure-sensitive adhesive layer, and a bonding adhesive layer composed of the above-described film-like adhesive in this order.

Still another aspect of the present disclosure relates to a semiconductor device. This semiconductor device includes a semiconductor element, a support member on which the semiconductor element is mounted, and a bonding adhesive member provided between the semiconductor element and the support member and bonding the semiconductor element and the support member. The bonding adhesive member is a cured product of the above-described film-like adhesive. The semiconductor device may further include another semiconductor element stacked on the semiconductor element.

Still another aspect of the present disclosure relates to a method for producing a semiconductor device. An embodiment of this method for producing a semiconductor device includes interposing the above-described film-like adhesive between a semiconductor element and a support member or between a first semiconductor element and a second semiconductor element, and bonding the semiconductor element and the support member or the first semiconductor element and the second semiconductor element.

Another embodiment of this method for producing a semiconductor device includes pasting the bonding adhesive layer of the above-described integrated dicing/die bonding film to a semiconductor wafer, dicing the semiconductor wafer to which the bonding adhesive layer is pasted, expanding the base material layer under a cooling condition to produce a plurality of singulated bonding adhesive piece-attached semiconductor elements, picking up the bonding adhesive piece-attached semiconductor element from the pressure-sensitive adhesive layer, and bonding the picked-up bonding adhesive piece-attached semiconductor element to a support member with a bonding adhesive piece interposed therebetween. In this case, the method for producing a semiconductor device may further include bonding the other bonding adhesive piece-attached semiconductor element to a surface of the semiconductor element bonded to the support member with a bonding adhesive piece interposed therebetween.

The present disclosure provides [1] to [15].

[1] A film-like adhesive containing an epoxy resin, a phenolic resin, an elastomer, and an inorganic filler, in which
a ratio of an epoxy group of the epoxy resin with respect to a hydroxyl group of the phenolic resin is 1.2 or more.
   [2] The film-like adhesive described in [1], in which the elastomer includes an elastomer satisfying the following Condition (i) and the following Condition (ii):
Condition (i): a glass transition temperature is 10° C. or higher; and
Condition (ii): a weight average molecular weight is 1000000 or less.
   [3] The film-like adhesive described in [1] or [2], in which a total content of the epoxy resin and the phenolic resin is 5 to 25% by mass based on the total amount of the film-like adhesive.
   [4] The film-like adhesive described in any one of [1] to [3], in which an average particle diameter of the inorganic filler is 400 nm or less.
   [5] The film-like adhesive described in any one of [1] to [4], in which a content of the inorganic filler is 18 to 40% by mass based on the total amount of the film-like adhesive.
   [6] The film-like adhesive described in any one of [1] to [5], in which a thickness is 25 μm or less.
   [7] The film-like adhesive described in any one of [1] to [6], which is used in a production process of a semiconductor device obtained by stacking a plurality of semiconductor elements.
   [8] The film-like adhesive described in [7], in which the semiconductor device is a three-dimensional NAND type memory.
   [9] A method for producing a film-like adhesive, the method including:
applying a varnish of a bonding adhesive composition containing an epoxy resin, a phenolic resin, an elastomer, an inorganic filler, and a solvent to a support film; and
removing the solvent from the applied varnish by heating and drying to obtain a film-like adhesive, in which
a ratio of an epoxy group of the epoxy resin with respect to a hydroxyl group of the phenolic resin is 1.2 or more.
   [10] An integrated dicing/die bonding film including a base material layer, a pressure-sensitive adhesive layer, and a bonding adhesive layer composed of the film-like adhesive described in any one of [1] to [6] in this order.
   [11] A semiconductor device including:
a semiconductor element;
a support member on which the semiconductor element is mounted; and
a bonding adhesive member provided between the semiconductor element and the support member and bonding the semiconductor element and the support member, in which
the bonding adhesive member is a cured product of the film-like adhesive described in any one of [1] to [6].
   [12] The semiconductor device described in [11], further including another semiconductor element stacked on the semiconductor element.
   [13] A method for producing a semiconductor device, the method including interposing the film-like adhesive described in any one of [1] to [6] between a semiconductor element and a support member or between a first semiconductor element and a second semiconductor element, and bonding the semiconductor element and the support member or the first semiconductor element and the second semiconductor element.
   [14] A method for producing a semiconductor device, the method including:
pasting the bonding adhesive layer of the integrated dicing/die bonding film described in [10] to a semiconductor wafer;
dicing the semiconductor wafer to which the bonding adhesive layer is pasted;
expanding the base material layer under a cooling condition to produce a plurality of singulated bonding adhesive piece-attached semiconductor elements;
picking up the bonding adhesive piece-attached semiconductor element from the pressure-sensitive adhesive layer; and bonding the picked-up bonding adhesive piece-attached semiconductor element to a support member with a bonding adhesive piece interposed therebetween.
   [15] The method for producing a semiconductor device described in [14], further including bonding the other bonding adhesive piece-attached semiconductor element to a surface of the semiconductor element bonded to the support member with a bonding adhesive piece interposed therebetween.

### Advantageous Effects of Invention

According to the present disclosure, there are provided a film-like adhesive capable of sufficiently maintaining adhesiveness even at the time of a high-temperature treatment and a method for producing the same. Some embodiments of the film-like adhesive are also excellent in ease of splitting by cooling expansion. Furthermore, according to the present disclosure, there are provided an integrated dicing/die bonding film, and a semiconductor device and a method for producing the same, which use such a film-like adhesive. Further, according to the present disclosure, there is provided a method for producing a semiconductor device using such an integrated dicing/die bonding film.

### BRIEF DESCRIPTION OF DRAWINGS

FIG. 1 is a schematic cross-sectional view illustrating an embodiment of a film-like adhesive.

FIG. 2 is a perspective view schematically illustrating a sample in a state of being fixed to a jig in a break test.

FIG. 3 is a cross-sectional view schematically illustrating a state where a load is applied to a sample by a pushing jig in a break test.

FIG. 4 is a graph schematically showing an example of results of a break test.

FIG. 5 is a schematic cross-sectional view illustrating an embodiment of an integrated dicing/die bonding film.

FIG. 6 is a schematic cross-sectional view illustrating an embodiment of a semiconductor device.

FIG. 7 is a schematic cross-sectional view illustrating another embodiment of the semiconductor device.

FIG. 8 is a schematic cross-sectional view illustrating still another embodiment of the semiconductor device.

### DESCRIPTION OF EMBODIMENTS

Hereinafter, embodiments of the present disclosure will be described with reference to the drawings as appropriate. However, the present disclosure is not limited to the following embodiments. In the following embodiments, the constituent elements (including a step or the like) are not always indispensable unless otherwise specified. The sizes of constituent elements in the respective drawings are conceptual, and the relative size relationships between the constituent elements are not restricted to those illustrated in the respective drawings.

The same applies to numerical values and ranges thereof in the present disclosure, and does not limit the present disclosure. In the present specification, a numerical range that has been indicated by use of “to” indicates the range that includes the numerical values which are described before and after “to”, as the minimum value and the maximum value, respectively. In the numerical ranges that are described stepwise in the present specification, the upper limit value or the lower limit value described in a numerical range may be replaced with the upper limit value or the lower limit value in another numerical range that is described stepwise. Furthermore, in a numerical range described in the present specification, the upper limit value or the lower limit value of the numerical range may be replaced with a value shown in the Examples.

In the present specification, (meth)acrylate means acrylate or methacrylate corresponding thereto. The same applies to other analogous expressions such as a (meth)acryloyl group and a (meth)acrylic copolymer.

Each of components and materials exemplified in the present specification may be used singly or may be used in combination of two or more kinds thereof, unless otherwise specified.

### [Film-Like Adhesive]

A film-like adhesive contains an epoxy resin (hereinafter, referred to as “component (A)” in some cases), a phenolic resin (hereinafter, referred to as “component (B)” in some cases), an elastomer (hereinafter, referred to as “component (C)” in some cases), and an inorganic filler (hereinafter, referred to as “component (D)” in some cases). The film-like adhesive may further contain, in addition to the component (A), the component (B), the component (C), and the component (D), a coupling agent (hereinafter, referred to as “component (E)” in some cases), a curing accelerator (hereinafter, referred to as “component (F)” in some cases), other components, and the like.

The film-like adhesive can be obtained by molding a bonding adhesive composition, which contains the component (A), the component (B), the component (C), and the component (D), and other components (the component (E), the component (F), other components, and the like) to be added as necessary, into a film shape. The film-like adhesive (bonding adhesive composition) may go through a semi-cured (B-stage) state and then reach a completely cured (C-stage) state after a curing treatment.

### Component (A): Epoxy Resin

The component (A) can be used without particular limitation as long as it has an epoxy group in the molecule. Examples of the component (A) include a bisphenol A type epoxy resin; a bisphenol F type epoxy resin; a bisphenol S type epoxy resin; a phenol novolac type epoxy resin; a cresol novolac type epoxy resin; a bisphenol A novolac type epoxy resin; a bisphenol F novolac type epoxy resin; a stilbene type epoxy resin; a triazine skeleton-containing epoxy resin; a fluorene skeleton-containing epoxy resin; a triphenolmethane type epoxy resin; a biphenyl type epoxy resin; a xylylene type epoxy resin; a biphenyl aralkyl type epoxy resin; a naphthalene type epoxy resin; and a diglycidyl ether compound of a polyfunctional phenol and a polycyclic aromatic compound, such as anthracene. These may be used singly or in combination of two or more kinds thereof. Among these, the component (A) may include a cresol novolac type epoxy resin from the viewpoint of tackiness, flexibility, and the like of the film.

The epoxy equivalent of the component (A) is not particularly limited, and may be 90 to 300 g/eq, 100 to 290 g/eq, or 110 to 280 g/eq. When the epoxy equivalent of the component (A) is in such a range, there is a tendency that more favorable reactivity and fluidity are obtained.

### Component (B): Phenolic Resin

The component (B) may be a polycondensation product of a phenol such as phenol, cresol, resorcin, catechol, bisphenol A, bisphenol F, phenylphenol, or aminophenol and/or a naphthol such as a-naphthol, β-naphthol, or dihydroxynaphthalene with an aldehyde such as formaldehyde. Polycondensation is usually performed in the presence of a catalyst such as an acid or a base. A phenolic resin obtained in the case of using an acid catalyst is particularly called a novolac type phenolic resin. Examples of the novolac type phenolic resin include a phenol/formaldehyde novolac resin, a cresol/formaldehyde novolac resin, a xylylenol/formaldehyde novolac resin, a resorcinol/formaldehyde novolac resin, and a phenol-naphthol/formaldehyde novolac resin. Furthermore, examples of the phenolic resin include a phenol aralkyl resin synthesized from a phenol such as allylated bisphenol A, allylated bisphenol F, allylated naphthalenediol, phenol novolac, or phenol and/or a naphthol with dimethoxyparaxylene or bis(methoxymethyl)biphenyl, a naphthol aralkyl resin, a biphenyl aralkyl type phenolic resin, and a phenyl aralkyl type phenolic resin.

The hydroxyl equivalent of the component (B) may be 80 to 250 g/eq, 90 to 200 g/eq, or 100 to 180 g/eq. When the hydroxyl equivalent of the component (B) is 80 g/eq or more, there is a tendency that the storage elastic modulus is further improved, and when the hydroxyl equivalent thereof is 250 g/eq or less, defects caused by generation of foam, outgas, or the like can be prevented.

The softening point of the component (B) may be 50 to 140° C., 55 to 115° C., or 60 to 100° C. Note that, the softening point means a value as measured by a ring and ball method in accordance with JIS K 7234.

A ratio (equivalent ratio) of an epoxy group of the component (A) with respect to a hydroxyl group of the component (B) (the number of epoxy groups of the component (A)/the number of hydroxyl groups of the component (B)) is 1.2 or more. When this ratio (equivalent ratio) is 1.2 or more, the film-like adhesive can sufficiently maintain adhesiveness even at the time of a high-temperature treatment. This ratio (equivalent ratio) may be 1.3 or more, 1.4 or more, 1.5 or more, 1.6 or more, 1.8 or more, or 2.0 or more. The upper limit of this ratio (equivalent ratio) may be, for example, 5.0 or less, 4.5 or less, 4.0 or less, 3.8 or less, or 3.6 or less.

In the case of using one kind of the component (A) and one kind of the component (B), the ratio of the epoxy group of the component (A) with respect to the hydroxyl group of the component (B) can be determined from the following equation.

$$Ratio = [ Charged amount of component ( A ) /$$

$$Epoxy equivalent of component ( A ) ] /$$

$$[ Charged amount of component ( B ) /$$

$$Hydroxyl equivalent of component ( B ) ]$$

In the case of using m kinds (m≥1) of the component (A) and n kinds (n≥1) of the component (B), the ratio of the epoxy group of the component (A) with respect to the hydroxyl group of the component (B) can be determined by the following equation.

$$Ratio = [ ( Charged amount of ( A 1 ) / Epoxy equivalent of ( A 1 ) ) + … +$$

$$( Charged amount of ( Am ) / Epoxy equivalent of ( Am ) ) ] /$$

$$[ ( Charged amount of ( B 1 ) / Hydroxyl equivalent of ( B 1 ) ) + … +$$

$$( Charged amount of ( Bn ) / Hydroxyl equivalent of ( Bn ) ) ]$$

Here, (A1), . . . , (Am) mean m kinds of the component (A), and (B1), . . . , (Bn) mean n kinds of the component (B).

A total content of the component (A) and the component (B) may be 5 to 25% by mass based on the total amount of the film-like adhesive. When the total content of the component (A) and the component (B) is 5% by mass or more based on the total amount of the film-like adhesive, there is a tendency that the adhesion maintainability of the film-like adhesive at the time of a high-temperature treatment is even more improved. When the total content of the component (A) and component (B) is 25% by mass or less based on the total amount of the film-like adhesive, there is a tendency that handling property or thin film coatability are more excellent. The total content of the component (A) and the component (B) may be 8% by mass or more, 10% by mass or more, or 12% by mass or more, and may be 22% by mass or less, 20% by mass or less, or 18% by mass or less, based on the total amount of the film-like adhesive.

### Component (C): Elastomer

Examples of the component (C) include an acrylic resin, a polyester resin, polyamide resin, polyimide resin, a silicone resin, a butadiene resin; and modified products of these resins. These may be used singly or in combination of two or more kinds thereof. Among these, from the viewpoints that ionic impurities are small and heat resistance is more excellent, that the connection reliability of the semiconductor device is more easily ensured, and that fluidity is more excellent, the component (C) may be an acrylic resin (acrylic rubber) having a structural unit derived from a (meth)acrylic acid ester as a main component. A content of the structural unit derived from a (meth)acrylic acid ester in the component (C) may be, for example, 70% by mass or more, 80% by mass or more, or 90% by mass or more based on the total amount of structural units. The acrylic resin (acrylic rubber) may include a structural unit derived from a (meth)acrylic acid ester having a cross-linkable functional group such as an epoxy group, an alcoholic or phenolic hydroxyl group, or a carboxyl group.

Among these, the component (C) may contain an elastomer satisfying Condition (i) and Condition (ii) (hereinafter, referred to as “component (C1)” in some cases).
Condition (i): A glass transition temperature is 10° C. or higher.
Condition (ii): A weight average molecular weight is 1000000 or less.

Regarding Condition (i), the glass transition temperature (Tg) of the component (C1) may be 10° C. or higher, and may be 12° C. or higher, 15° C. or higher, 18° C. or higher, or 20° C. or higher. When the Tg of the component (C1) is 10° C. or higher, there is a tendency that the adhesive strength of the film-like adhesive can be further improved, and the flexibility of the film-like adhesive can be prevented from becoming too high. Therefore, by using such a component (C1), the ease of splitting of the film-like adhesive in cooling expansion can be even more improved. The upper limit of the Tg of the component (C1) is not particularly limited, and may be, for example, 55° C. or lower, 50° C. or lower, 45° C. or lower, 40° C. or lower, 35° C. or lower, 30° C. or lower, or 25° C. or lower. When the Tg of the component (C1) is 55° C. or lower, there is a tendency that a decrease in the flexibility of the film-like adhesive can be suppressed. According to this, there is a tendency that voids are easily and sufficiently embedded when the film-like adhesive (bonding adhesive layer) is pasted to the semiconductor wafer. Furthermore, chipping at the time of dicing caused by a decrease in adhesion to the semiconductor wafer can be prevented. Herein, the glass transition temperature (Tg) means a value measured using DSC (thermal differential scanning calorimeter) (for example, Thermo Plus 2 manufactured by Rigaku Corporation). The Tg of the component (C1) can be adjusted to a desired range by adjusting the type and content of the structural unit constituting the component (C1) (the structural unit derived from a (meth)acrylic acid ester in a case where the component (C1) is an acrylic resin (acrylic rubber)).

Regarding Condition (ii), the weight average molecular weight (Mw) of the component (C1) may be 1000000 or less, and may be 900000 or less or 800000 or less. The lower limit of the Mw of the component (C1) is not particularly limited, and may be, for example, 10000 or more, 50000 or more, 100000 or more, 300000 or more, or 500000 or more. When the Mw of the component (C1) is in such a range, the ease of splitting in cooling expansion of the film, film formability, film strength, flexibility, tackiness, and the like can properly controlled, reflow properly is excellent, and embeddability can be improved. Herein, the Mw means a value as measured by gel permeation chromatography (GPC) and converted using a calibration curve of standard polystyrene.

A content of the component (C1) may be 50 to 100% by mass, 70 to 100% by mass, 90 to 100% by mass, or 95 to 100% by mass based on the total amount of the component (C). The content of the component (C1) may be 100% by mass based on the total amount of the component (C).

The component (C) may contain, in addition to the component (C1), an elastomer not satisfying the requirements of the component (C1) (hereinafter, referred to as “component (C2)” in some cases).

A content of the component (C2) may be 0 to 50% by mass, 0 to 30% by mass, 0 to 10% by mass, or 0 to 5% by mass based on the total amount of the component (C). The content of the component (C2) may be 0% by mass based on the total amount of the component (C). That is, the component (C) may not contain the component (C2).

A content of the component (C) may be 40% by mass or more, 45% by mass or more, or 50% by mass or more based on the total amount of the film-like adhesive. When the content of the component (C) is in such a range, there is a tendency that the thin film coatability is more excellent. The content of the component (C) may be 80% by mass or less, 75% by mass or less, or 70% by mass or less based on the total amount of the film-like adhesive. When the content of the component (C) is in such a range, the content of the component (A) and the component (B) can be sufficiently secured, and there is a tendency that compatibility with other properties can be achieved.

### Component (D): Inorganic Filler

Examples of the inorganic filler as the component (D) include aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whisker, boron nitride, and silica. These may be used singly or in combination of two or more kinds thereof. Of these, the inorganic filler may be silica from the viewpoint of adjusting the melt viscosity. The shape of the inorganic filler is not particularly limited, and may be spherical.

An average particle diameter of the component (D) may be 400 nm or less, and may be 350 nm or less, 300 nm or less, 250 nm or less, or 200 nm or less, from the viewpoint of thin film coatability and adhesiveness. The average particle diameter of the component (D) may be, for example, 10 nm or more, 30 nm or more, 50 nm or more, 100 nm or more, or 150 nm or more. When the average particle diameter of the component (D) is 400 nm or less, there is a tendency that thin film coatability is excellent. When the average particle diameter of the component (D) is 10 nm or more, there is a tendency that the adhesive force is excellent. Here, the average particle diameter of the component (D) can be determined by the following method. First, the component (D) is dispersed in a solvent to produce a dispersion. Next, a dynamic light scattering method is applied to the produced dispersion to obtain a particle size distribution. Next, the average particle diameter of the component (D) can be determined based on the obtained particle size distribution. Note that, the average particle diameter of the component (D) can also be determined from the film-like adhesive containing the component (D). In this case, the residue obtained by heating the film-like adhesive to decompose the resin component is dispersed in a solvent to produce a dispersion. Next, a dynamic light scattering method is applied to the produced dispersion to obtain a particle size distribution. Next, the average particle diameter of the component (D) can be determined based on the obtained particle size distribution.

The component (D) may be configured by, for example, one or two or more kinds of inorganic fillers having an average particle diameter of 400 nm or less, and may be configured by one or two or more kinds of inorganic fillers having an average particle diameter of 10 to 400 nm, an average particle diameter of 30 to 400 nm, an average particle diameter of 50 to 400 nm, an average particle diameter of 100 to 400 nm, an average particle diameter of 150 to 400 nm, an average particle diameter of 10 to 350 nm, an average particle diameter of 30 to 350 nm, an average particle diameter of 50 to 350 nm, an average particle diameter of 100 to 350 nm, an average particle diameter of 150 to 350 nm, an average particle diameter of 10 to 300 nm, an average particle diameter of 30 to 300 nm, an average particle diameter of 50 to 300 nm, an average particle diameter of 100 to 300 nm, an average particle diameter of 150 to 300 nm, an average particle diameter of 10 to 250 nm, an average particle diameter of 30 to 250 nm, an average particle diameter of 50 to 250 nm, an average particle diameter of 100 to 250 nm, an average particle diameter of 150 to 250 nm, an average particle diameter of 10 to 200 nm, an average particle diameter of 30 to 200 nm, an average particle diameter of 50 to 200 nm, an average particle diameter of 100 to 200 nm, or an average particle diameter of 150 to 200 nm.

A content of the component (D) may be 18 to 40% by mass based on the total amount of the film-like adhesive. When the content of the component (D) is 18% by mass or more, there is a tendency that the ease of splitting by cooling expansion is excellent. When the content of the component (D) is 18% by mass or more and 40% by mass or less, there is a tendency that the adhesive force is easily improved. The content of the component (D) may be 20% by mass or more, 22% by mass or more, or 24% by mass or more, and may be 38% by mass or less, 35% by mass or less, 32% by mass or less, or 30% by mass or less, based on the total amount of the film-like adhesive.

### Component (E): Coupling Agent

The component (E) may be a silane coupling agent. Examples of the silane coupling agent include γ-ureidopropyltriethoxysilane, γ-mercaptopropyltrimethoxysilane, 3-phenylaminopropyltrimethoxysilane, and 3-(2-aminoethyl)aminopropyltrimethoxysilane.

### Component (F): Curing Accelerator

Examples of the component (F) include imidazoles and derivatives thereof, an organic phosphorus-based compound, secondary amines, tertiary amines, and a quaternary ammonium salt. These may be used singly or in combination of two or more kinds thereof. Of these, the component (F) may be imidazoles and derivatives thereof from the viewpoint of reactivity.

Examples of the imidazoles include 2-methylimidazole, 1-benzyl-2-methylimidazole, 1-cyanoethyl-2-phenylimidazole, and 1-cyanoethyl-2-methylimidazole. These may be used singly or in combination of two or more kinds thereof.

The film-like adhesive may further contain other components. Examples of the other components include a pigment, an ion scavenger, and an antioxidant.

A total content of the component (E), the component (F), and other components may be 0.01% by mass or more, 0.1% by mass or more, or 0.3% by mass or more, and may be 20% by mass or less, 10% by mass or less, 5% by mass or less, 3% by mass or less, or 1% by mass or less, based on the total amount of the film-like adhesive.

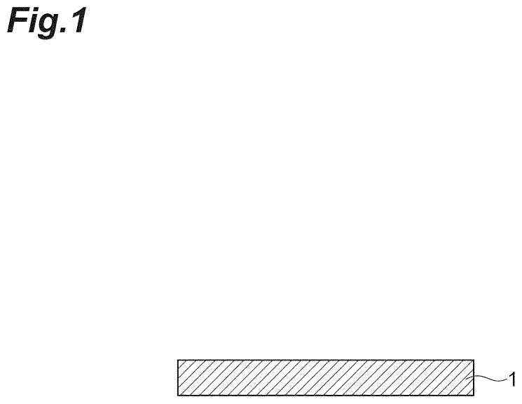

FIG. 1 is a schematic cross-sectional view illustrating an embodiment of a film-like adhesive. A film-like adhesive 1 illustrated in FIG. 1 is produced by molding a bonding adhesive composition into a film shape. The film-like adhesive 1 is usually in a semi-cured (B-stage) state, and may reach a completely cured (C-stage) state after a curing treatment. The film-like adhesive 1 can be formed by applying a bonding adhesive composition to a support film. In the formation of the film-like adhesive 1, a varnish of a bonding adhesive composition (bonding adhesive varnish) may be used. The bonding adhesive varnish can be prepared, for example, by mixing or kneading the component (A), the component (B), the component (C), and the component (D), and components to be added as necessary in a solvent. In one embodiment, the film-like adhesive 1 can be produced by a method including applying a varnish of a bonding adhesive composition (bonding adhesive varnish) containing the component (A), the component (B), the component (C), the component (D), and a solvent to a support film, and removing the solvent from the applied varnish (bonding adhesive varnish) by heating and drying. At this time, the ratio of the epoxy group of the epoxy resin with respect to the hydroxyl group of the phenolic resin is 1.2 or more. The step of removing the solvent from the applied bonding adhesive varnish by heating and drying may be removing at least a part of the solvent from the applied bonding adhesive varnish by heating and drying. That is, a small amount of the solvent may remain in the film-like adhesive 1 obtained after the step of removing the solvent from the applied bonding adhesive varnish by heating and drying.

The support film is not particularly limited as long as it can withstand the above-described heating and drying, and may be, for example, a polyester film, a polypropylene film, a polyethylene terephthalate film, a polyimide film, a polyether imide film, a polyethylene naphthalate film, a polymethylpentene film, or the like. The support film may be a multi-layer film obtained by combination of two or more kinds of films, and the surface thereof may be treated with a silicone-based, silica-based, or other release agent, and the like. A thickness of the support film may be, for example, 10 to 200 μm or 20 to 170 μm.

The mixing or kneading can be performed by using conventional dispersers such as a stirrer, a Raikai mixer, a three-roll mill, and a ball mill, and appropriately combining these.

The solvent for preparing the bonding adhesive varnish is not limited as long as it can uniformly dissolve, knead, or disperse each component, and a conventionally known organic solvent can be used. Examples of such a solvent include a ketone-based solvent such as acetone, methyl ethyl ketone, methyl isobutyl ketone, and cyclohexanone, dimethylformamide, dimethylacetamide, N-methylpyrrolidone, toluene, and xylene. The solvent may be methyl ethyl ketone or cyclohexanone from the viewpoint of the drying speed and cost.

As the method of applying the bonding adhesive varnish to the support film, known methods can be used, and for example, a knife coating method, a roll coating method, a spray coating method, a gravure coating method, a bar coating method, and a curtain coating method, and the like can be used. The heating and drying are not particularly limited as long as they are under a condition that the used solvent vaporizes sufficiently, and can be performed in a range of 50 to 150° C. and for a range of 1 to 30 minutes. The heating and drying can be performed stepwise at different heating temperatures for different heating times.

A thickness of the film-like adhesive may be 25 μm or less, and may be 22 μm or less, 20 μm or less, 18 μm or less, 15 μm or less, 12 μm or less, or 10 μm or less. The lower limit of the thickness of the film-like adhesive is not particularly limited, and may be, for example, 1 μm or more.

The film-like adhesive produced on the support film may include a cover film on a side opposite to the support film of the film-like adhesive from the viewpoint of preventing damage or contamination. Examples of the cover film include a polyethylene film, a polypropylene film, and a surface release agent-treated film. A thickness of the cover film may be, for example, 15 to 200 μm or 30 to 170 μm.

Since the film-like adhesive can be made thin, the film-like adhesive can be suitably used in a production process of a semiconductor device obtained by stacking a plurality of semiconductor elements. In this case, the semiconductor device may be a stacked MCP, and may be a three-dimensional NAND type memory.

The film-like adhesive 1 may be a film-like adhesive having a breaking factor m of 70 or less in a method for evaluating an ease of splitting which utilizes the results of a break test to be performed under the following conditions (a method for evaluating an ease of splitting of a film-like adhesive under a low temperature condition (for example, in a range of −15° C. to 0° C.) in which cooling expansion is performed).

### <Conditions>

Sample width: 5 mm
Sample length: 23 mm
Relative speed between a pushing jig and a sample: 10 mm/min

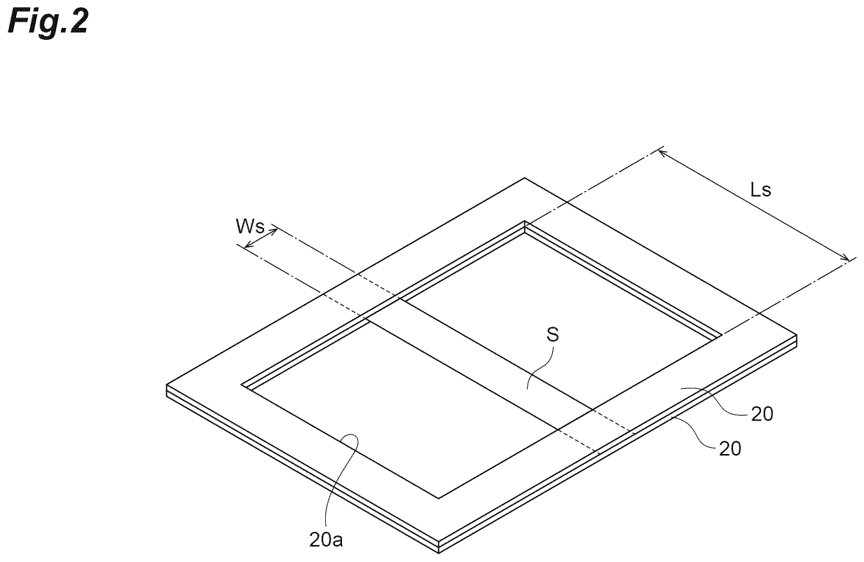

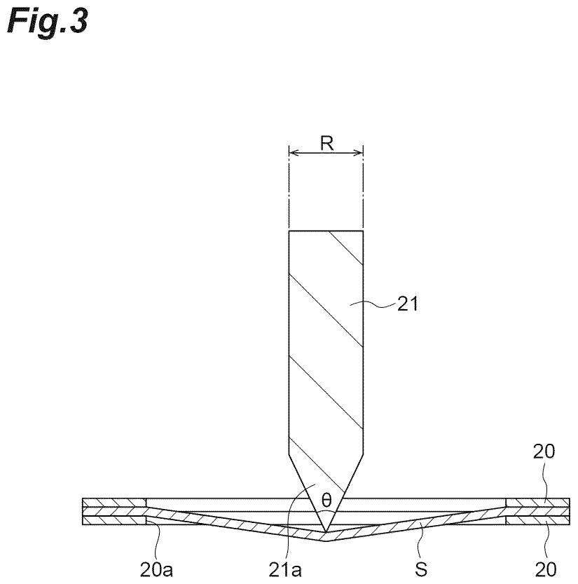

Hereinafter, the break test will be described. The break test is classified as a transverse rupture strength test and includes pushing the center portion of the sample until the sample is broken in a state where both ends of the sample are fixed. As illustrated in FIG. 2, a sample S is provided to a break test in a state where the sample is fixed by being sandwiched between a pair of sample fixing jigs 20. The pair of sample fixing jigs 20 is made of, for example, thick paper having a sufficient strength and each has a rectangular opening 20a at the center. A load is applied to the center portion of the sample S in a fixed state by a pushing jig 21 (see FIG. 3).

The sample S may be obtained by cutting the film-like adhesive as an evaluation target, and it is not necessary to produce a sample by stacking a plurality of adhesive pieces cut from the film-like adhesive. That is, a thickness of the sample S may be the same as the thickness of the film-like adhesive. The width (Ws in FIG. 2) of the sample S is, for example, 1 to 30 mm and may be 3 to 8 mm. The width thereof may be set to an appropriate width according to the status of a measurement apparatus. The length (Ls in FIG. 2) of the sample S is, for example, 5 to 50 mm and may be 10 to 30 mm or 6 to 9 mm. The length of the sample S depends on the size of opening 20a of the sample fixing jig 20. Note that, the shape of the sample fixing jig 20 and the size of the sample S may be other than those described above as long as a break test can be performed.

The pushing jig 21 is composed of a cylindrical member having a conical tip portion 21a. The diameter (R in FIG. 3) of the pushing jig 21 is, for example, 3 to 15 mm and may be 5 to 10 mm. The angle (0 in FIG. 3) of the tip portion 21a is, for example, 40 to 120° and may be 60 to 100°.

The break test is performed in a thermostat bath set at a predetermined temperature. The thermostat bath may be set to a certain temperature in a range of −15° C. to 0° C. (temperature of cooling expansion to be assumed). As the thermostat bath, for example, TLF-R3-F-W-PL-S manufactured by AETEC Co., Ltd. can be used. A breaking work W, a breaking strength P, and a breaking elongation L are obtained using an autograph (for example, AZT-CA01 manufactured by A&D Company, Limited, load cell 50 N, compression mode).

The relative speed between the pushing jig 21 and the sample S is, for example, 1 to 100 mm/min and may be 5 to 20 mm/min. When this relative speed is too fast, there is a tendency that data of breaking process cannot be sufficiently acquired, and when the relative speed is too slow, there is a tendency that stress is alleviated and thus breaking is not enough. The pushing distance of the pushing jig 21 is, for example, 1 to 50 mm and may be 5 to 30 mm. When the pushing distance is too short, there is a tendency that breaking is not enough. Regarding the film-like adhesive as an evaluation target, it is preferable that a plurality of samples are prepared, the break test is performed in plural times, and then the stability of test results is checked.

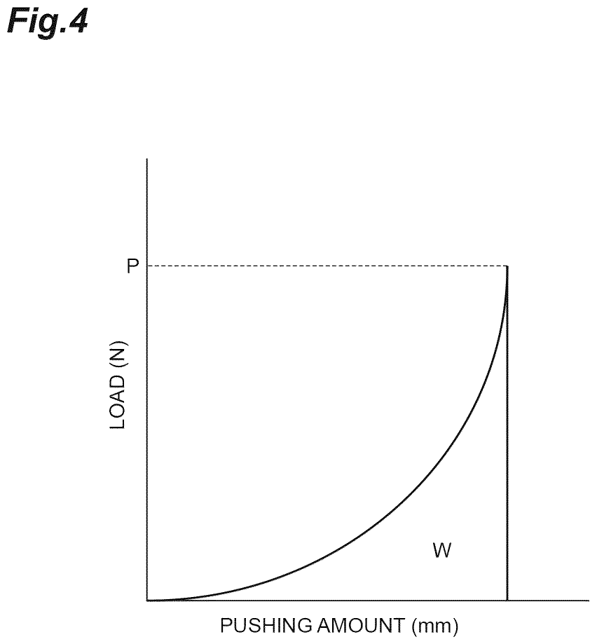

FIG. 4 is a graph showing an example of results of a break test. As shown in FIG. 4, the breaking work W is a surrounded area when a graph is created while the vertical axis represents a load and the horizontal axis represents a pushing amount until the sample S is broken. The breaking strength P is a load when the sample S is broken. The breaking elongation L is an elongation amount of the sample S when the sample S is broken. The breaking elongation L may be calculated using a trigonometric function from the pushing distance when the sample S is broken and the width of the opening 20a of the sample fixing jig 20.

The breaking factor n (non-dimensional) and the breaking resistance R (N/mm²) are obtained by Equation (1) and Equation (2) from values of the breaking work W (N·mm), the breaking strength P (N), and the breaking elongation L (mm) obtained by the break test.

$$m = W / [ 1000 \times ( P \times L ) ] \qquad ( 1 )$$

$$R = P / A \qquad ( 2 )$$

According to the studies of the present inventors, when the break test is performed under the following conditions, there is a tendency that a film-like adhesive having a breaking factor m of 70 or less has excellent ease of splitting practically at the time of cooling expansion in stealth dicing.

### <Conditions>

Sample width: 5 mm
Sample length: 23 mm
Relative speed between a pushing jig and a sample: 10 mm/min

### [Integrated Dicing/Die Bonding Film]

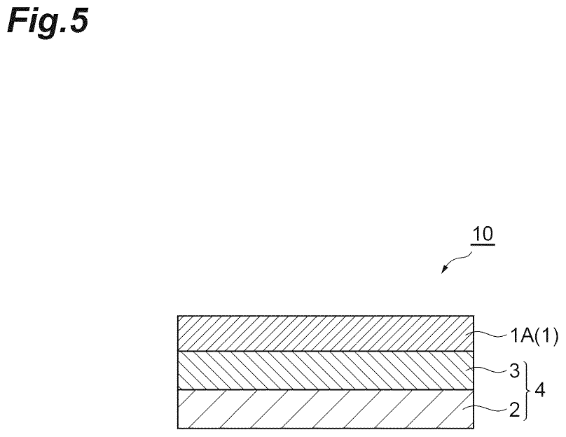

FIG. 5 is a schematic cross-sectional view illustrating an embodiment of an integrated dicing/die bonding film. An integrated dicing/die bonding film 10 illustrated in FIG. 5 includes a base material layer 2, a pressure-sensitive adhesive layer 3, and a bonding adhesive layer 1A composed of the film-like adhesive 1 (bonding adhesive composition) in this order. The base material layer 2 and the adhesive layer 3 may be a dicing film 4. When such an integrated dicing/die bonding film 10 is used, the lamination step of the semiconductor wafer to be bonded to the semiconductor wafer is performed once, so that work efficiency can be achieved. The Integrated dicing/die bonding film may be in the form of a film, a sheet, a tape, or the like.

The dicing film 4 includes the base material layer 2 and the pressure-sensitive adhesive layer 3 provided on the base material layer 2.

Examples of the base material layer 2 include plastic films such as a polytetrafluoroethylene film, a polyethylene terephthalate film, a polyethylene film, a polypropylene film, a polymethylpentene film, and a polyimide film. These base material layers 2 may be subjected to, as necessary, a surface treatment such as a primer application, a UV treatment, a corona discharge treatment, a polishing treatment, and an etching treatment.

The pressure-sensitive adhesive layer 3 is a layer composed of a pressure-sensitive adhesive. The pressure-sensitive adhesive is not particularly limited as long as it has a sufficient adhesive force not to allow scattering of semiconductor elements at the time of dicing and a low adhesive force to the extent that semiconductor elements are not damaged in the subsequent step of a pickup step of the semiconductor chips, and a pressure-sensitive adhesive conventionally known in the field of dicing films can be used. The pressure-sensitive adhesive may be either radiation curable or non-radiation curable pressure-sensitive adhesive. A radiation curable pressure-sensitive adhesive is a pressure-sensitive adhesive having a property that adhesion is decreased by irradiation with radiation (for example, ultraviolet rays). The radiation curable pressure-sensitive adhesive may be, for example, an ultraviolet curable pressure-sensitive adhesive. On the other hand, the non-radiation curable pressure-sensitive adhesive is a pressure-sensitive adhesive showing a certain level of adhesion when a pressure is applied for a short time.

A thickness of the dicing film 4 (the base material layer 2 and the pressure-sensitive adhesive layer 3) may be 60 to 150 μm or 70 to 130 μm from the viewpoint of economic efficiency and handling property of the film.

The integrated dicing/die bonding film 10 can be obtained, for example, by preparing the film-like adhesive 1 and the dicing film 4 and pasting the film-like adhesive 1 and the pressure-sensitive adhesive layer 3 of the dicing film 4. Furthermore, the integrated dicing/die bonding film 10 can also be obtained, for example, by preparing the dicing film 4 and applying a bonding adhesive composition (bonding adhesive varnish) onto the pressure-sensitive adhesive layer 3 of the dicing film 4 in the same manner as in the above-described method of forming the film-like adhesive 1.

In a case where the film-like adhesive 1 and the pressure-sensitive adhesive layer 3 of the dicing film 4 are pasted to each other, the integrated dicing/die bonding film 10 can be formed by pasting the film-like adhesive 1 to the dicing film 4 under a predetermined condition (for example, room temperature (25° C.) or in a heated state) using a roll laminator, a vacuum laminator, or the like. The integrated dicing/die bonding film 10 can be continuously produced and is excellent in efficiency, so that the integrated dicing/die bonding film 10 may be formed using a roll laminator in a heated state.

The film-like adhesive and the integrated dicing/die bonding film may be used in a production process of a semiconductor device, and may be used in a production process of a semiconductor device obtained by stacking a plurality of semiconductor elements.

The film-like adhesive is also suitably used as a bonding adhesive for bonding a semiconductor element and a support member on which the semiconductor element is mounted.

Furthermore, the film-like adhesive is also suitably used as a bonding adhesive for bonding semiconductor elements to each other in a stacked MCP (for example, a three-dimensional NAND type memory) which is a semiconductor device obtained by stacking a plurality of semiconductor elements.

The film-like adhesive can also be used, for example, as a protective sheet for protecting a rear surface of a semiconductor element of a flip-chip type semiconductor device, a sealing seat for encapsulating a gap between a surface of a semiconductor element of a flip-chip type semiconductor device and an adherend, and the like.

A semiconductor device produced using the film-like adhesive and the integrated dicing/die bonding film will be specifically described hereinafter with reference to the drawings. Note that, semiconductor devices of various structures have been proposed in recent years, and use applications of the film-like adhesive and the integrated dicing/die bonding film of the present embodiment are not limited to the structure of a semiconductor device described below.

### [Semiconductor Device]

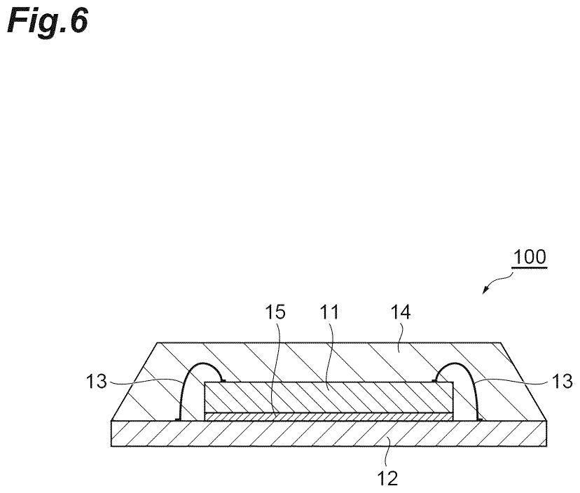

FIG. 6 is a schematic cross-sectional view illustrating an embodiment of a semiconductor device. A semiconductor device 100 illustrated in FIG. 6 includes a semiconductor element 11, a support member 12 on which the semiconductor element 11 is mounted, and a bonding adhesive member 15. The bonding adhesive member 15 is provided between the semiconductor element 11 and the support member 12, and bonds the semiconductor element 11 and the support member 12. The bonding adhesive member 15 is a cured product of the bonding adhesive composition (a cured product of the film-like adhesive). A connection terminal (not illustrated) of the semiconductor element 11 is electrically connected to an external connection terminal (not illustrated) via a wire 13 and is encapsulated by a sealing material 14.

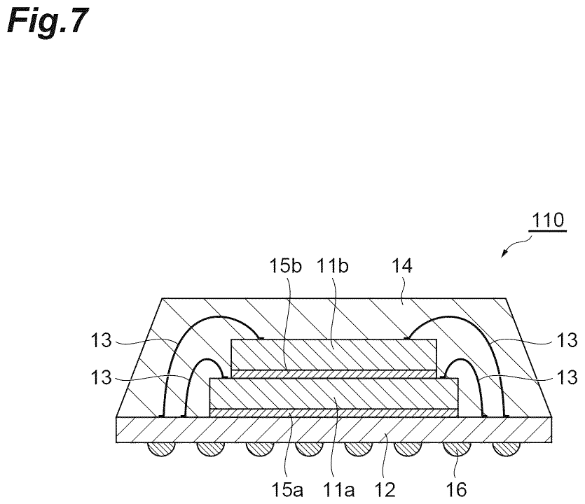

FIG. 7 is a schematic cross-sectional view illustrating another embodiment of the semiconductor device. In a semiconductor device 110 illustrated in FIG. 7, a first-level semiconductor element 11a is bonded to the support member 12 on which a terminal 16 is formed by a bonding adhesive member 15a (a cured product of the bonding adhesive composition (a cured product of the film-like adhesive)), and a second-level semiconductor element 11b is further bonded onto the first-level semiconductor element 11a by a bonding adhesive member 15b (a cured product of the bonding adhesive composition (a cured product of the film-like adhesive)). Connection terminals (not illustrated) of the first-level semiconductor element 11a and the second-level semiconductor element 11b are electrically connected with external connection terminals via the wires 13 and are encapsulated by the sealing material 14. It can also be said that the semiconductor device 110 illustrated in FIG. 7 further includes another semiconductor element (11b) stacked on the semiconductor element (11a) in the semiconductor device 100 illustrated in FIG. 6.

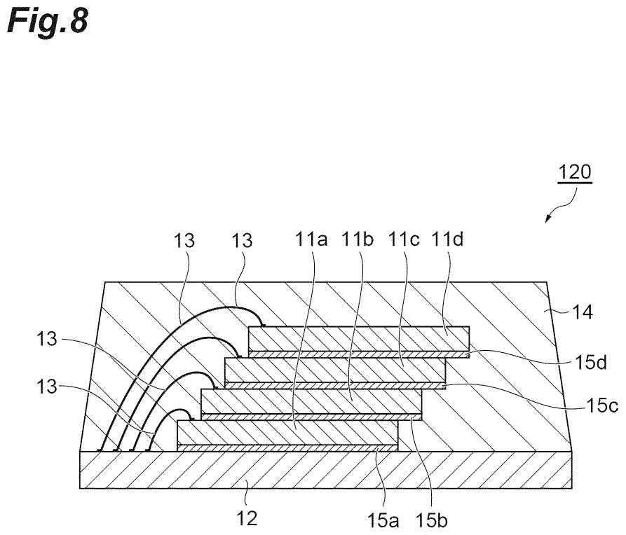

FIG. 8 is a schematic cross-sectional view illustrating still another embodiment of the semiconductor device. A semiconductor device 120 illustrated in FIG. 8 includes the support member 12 and semiconductor elements 11a, 11b, 11c, and 11d stacked on the support member 12. The four semiconductor elements 11a, 11b, 11c, and 11d are stacked at positions deviated from each other in a horizontal direction (a direction perpendicular to a stacking direction) for connection to connection terminals (not illustrated) formed on the surface of the support member 12 (see FIG. 8). The semiconductor element 11a is bonded to the support member 12 by the bonding adhesive member 15a (a cured product of the bonding adhesive composition (a cured product of the film-like adhesive)), and bonding adhesive member 15b, 15c, and 15d (a cured product of the bonding adhesive composition (a cured product of the film-like adhesive)) are also interposed among the three semiconductor elements 11b, 11c, and 11d, respectively. It can also be said that the semiconductor device 120 illustrated in FIG. 8 further includes other semiconductor elements (11b, 11c, and 11d) stacked on the semiconductor element (11a) in the semiconductor device 100 illustrated in FIG. 6.

Hereinbefore, embodiments of the present disclosure for the semiconductor device (package) have been described in detail, but the present disclosure is not limited to the above-described embodiments. For example, in FIG. 8, a semiconductor device having an embodiment in which four semiconductor elements are stacked has been exemplified, but the number of semiconductor elements to be stacked is not limited thereto. Furthermore, in FIG. 8, the semiconductor device of an embodiment in which semiconductor elements are stacked at positions deviated from each other in the horizontal direction (the direction perpendicular to the stacking direction) has been illustrated, but the semiconductor device may be an embodiment in which semiconductor elements are stacked at positions not deviated from each other in the horizontal direction (the direction perpendicular to the stacking direction).

### [Method for Producing Semiconductor Device]

The semiconductor devices (semiconductor packages) illustrated in FIG. 6, FIG. 7, and FIG. 8 can be obtained by a member including interposing the above-described film-like adhesive between a semiconductor element (semiconductor chip) and a support member or between a semiconductor element (first semiconductor element) and a semiconductor element (second semiconductor element), and bonding the semiconductor element and the support member or the semiconductor element (first semiconductor element) and the semiconductor element (second semiconductor element). More specifically, the semiconductor devices can be obtained by interposing the above-described film-like adhesive between a semiconductor element and a support member or between a semiconductor element (first semiconductor element) and a semiconductor element (second semiconductor element), heating and press-bonding these components to bond the two components together, and then performing, as necessary, a wire bonding step, an encapsulating step using a sealing material, and a heat melting step including reflow by solder, and the like.

The method of interposing the film-like adhesive between a semiconductor element and a support member or between a semiconductor element (first semiconductor element) and a semiconductor element (second semiconductor element) may be a method of producing a bonding adhesive piece-attached semiconductor element in advance and then pasting the bonding adhesive piece-attached semiconductor element to a support member or a semiconductor element as described below.

Next, an embodiment of a method for producing a semiconductor device using the integrated dicing/die bonding film illustrated in FIG. 5 will be described. Note that, the method for producing a semiconductor device by using the integrated dicing/die bonding film is not limited to the method for producing a semiconductor device described below.

The semiconductor device can be obtained, for example, by a method including pasting the bonding adhesive layer of the above-described integrated dicing/die bonding film to a semiconductor wafer (lamination step), dicing the semiconductor wafer to which the bonding adhesive layer is pasted (dicing step), expanding the base material layer under a cooling condition to produce a plurality of singulated bonding adhesive piece-attached semiconductor elements (bonding adhesive piece-attached semiconductor chips) (cooling expansion step), picking up the bonding adhesive piece-attached semiconductor element from the pressure-sensitive adhesive layer (pickup step), and bonding the picked-up bonding adhesive piece-attached semiconductor element to a support member with a bonding adhesive piece interposed therebetween (first bonding step). The method for producing a semiconductor device may further include bonding the other bonding adhesive piece-attached semiconductor element to a surface of the semiconductor element bonded to the support member with a bonding adhesive piece interposed therebetween (second bonding step).

The lamination step is press-bonding the bonding adhesive layer 1A in the integrated dicing/die bonding film 10 to a semiconductor wafer and bonding the bonding adhesive layer 1A and the semiconductor wafer by adhering and holding the bonding adhesive layer 1A. The present step may be performed while pressing with a pressing means such as a press-bonding roll. Note that, as the semiconductor wafer, the same semiconductor wafer as described above can be exemplified.

Examples of the semiconductor wafer include single crystal silicon, polycrystal silicon, various ceramics, and compound semiconductors such as gallium arsenide.

The dicing step is dicing the semiconductor wafer. Dicing can be performed, for example, from the circuit surface side of the semiconductor wafer according to an ordinary method. Furthermore, in the present step, for example, a method called half-cut in which a half-cut is provided on a semiconductor wafer, a method (stealth dicing) in which a modified region is formed and divided by a laser, and the like can be employed. The bonding adhesive layer of the above-described integrated dicing/die bonding film is excellent in the ease of splitting by cooling expansion, and thus stealth dicing is preferably employed. A dicing device to be used in the present step is not particularly limited, and a conventionally known device can be used.

The cooling expansion step is expanding the base material layer under a cooling condition. Thereby, a plurality of singulated bonding adhesive piece-attached semiconductor elements can be obtained. The expansion conditions under the cooling condition can be arbitrarily set, and for example, can be set such that the cooling temperature is −30 to 5° C., the cooling time is 30 seconds to 5 minutes, the thrust amount is 5 to 15 mm, and the thrust speed is 50 to 300 mm/sec.

Examples of the semiconductor element (semiconductor chip) include an IC (integrated circuit). Examples of the support member include lead frames such as an Alloy 42 lead frame and a copper lead frame; plastic films such as a polyimide resin and an epoxy resin; modified plastic films obtained by impregnating a base material such as a glass nonwoven fabric with a plastic such as a polyimide resin or an epoxy resin and curing the plastic; and ceramics such as alumina.

The pickup step is picking up the bonding adhesive piece-attached semiconductor element while separating the bonding adhesive piece-attached semiconductor elements from each other in order to peel off the bonding adhesive piece-attached semiconductor element adhesively fixed to the integrated dicing/die bonding film. The method of separating the bonding adhesive piece-attached semiconductor elements from each other is not particularly limited, and various conventionally known methods can be employed. The method of picking up the bonding adhesive piece-attached semiconductor element is not particularly limited, and various conventionally known methods can be employed. Examples of such a method include a method of thrusting individual bonding adhesive piece-attached semiconductor elements from the integrated dicing/die bonding film side by a needle, and picking up the thrust bonding adhesive piece-attached semiconductor element by a pickup device.

Here, the pickup step can be performed after the pressure-sensitive adhesive layer is irradiated with radiation in a case where the pressure-sensitive adhesive layer is a radiation (for example, ultraviolet rays) curable type. Thereby, the adhesive force of the pressure-sensitive adhesive layer with respect to the bonding adhesive piece is reduced, and peeling the bonding adhesive piece-attached semiconductor element becomes easier. As a result, the bonding adhesive piece-attached semiconductor element can be picked up without being damaged.

The first bonding step is bonding the picked-up bonding adhesive piece-attached semiconductor element to a support member for mounting a semiconductor element with a bonding adhesive piece interposed therebetween. Furthermore, the method may also include, as necessary, bonding the other bonding adhesive piece-attached semiconductor element to a surface of the semiconductor element bonded to the support member with a bonding adhesive piece interposed therebetween (second bonding step). Bonding can be performed by press-bonding in both of the bonding steps. The press-bonding conditions are particularly not limited, and can be appropriately set as necessary. The press-bonding conditions may be, for example, a temperature condition of 80 to 160° C., a load condition of 5 to 15 N, and a time condition of 1 to 10 seconds. Note that, as the support member, the same support member as described above can be exemplified.

The method for producing a semiconductor device may include thermally curing the bonding adhesive piece as necessary. According to the above-described bonding step, by thermally curing the bonding adhesive piece bonding the semiconductor element and the support member, or the semiconductor element (first semiconductor element) and the semiconductor element (second semiconductor element), adhesive fixation can be performed more firmly. In the case of performing thermal curing, curing may be performed by simultaneously applying pressure. The heating temperature in the present step can be appropriately changed depending on the constituent components of the bonding adhesive piece. The heating temperature may be, for example, 60 to 200° C. Note that, heating may be performed while changing the temperature or pressure stepwise.

The method for producing a semiconductor device may include, as necessary, electrically connecting a tip of a terminal part (inner lead) of the support member and an electrode pad on a semiconductor element by using a bonding wire (wire bonding step). As the bonding wire, for example, a gold wire, an aluminum wire, a copper wire, and the like are used. The temperature at the time of performing wire bonding (providing a bonding wire) may be within a range of 80 to 250° C. or 80 to 220° C. The heating time may be several seconds to several minutes. At the time of providing a bonding wire, wire bonding may be performed in a state where the bonding wire is heated within the above-described temperature range, by using the vibration energy of ultrasonic waves and the pressure-bonding energy of applied pressure in combination.

The method for producing a semiconductor device may include, as necessary, encapsulating semiconductor elements by a sealing material (encapsulating step). The present step is performed in order to protect the semiconductor elements or bonding wires mounted on the support member. The present step can be performed by molding a resin for encapsulation (encapsulation resin) in a mold. The encapsulation resin may be, for example, an epoxy-based resin. Due to the heat and pressure during encapsulation, the support member and residue are embedded, and detachment caused by air bubbles at the adhesive interface can be prevented.

The method for producing a semiconductor device may include, as necessary, completely curing the encapsulation resin that is insufficiently cured in the encapsulating step (post-curing step). Even in a case where the bonding adhesive piece is not thermally cured in the encapsulating step, the bonding adhesive piece is thermally cured together with curing of the encapsulation resin to enable adhesive fixation in the present step. The heating temperature in the present step can be appropriately set according to the type of the encapsulation resin, and for example, the heating temperature may be in a range of 165 to 185° C., and the heating time may be about 0.5 to 8 hours.

The method for producing a semiconductor device may include, as necessary, heating the bonding adhesive piece-attached semiconductor element bonded to the support member by using a reflow furnace (heat melting step). In the present step, the resin-encapsulated semiconductor device may be surface-mounted on a support member. Examples of the method for surface mounting include reflow soldering of supplying solder in advance onto a printed circuit board, and then heat melting solder by means of hot air or the like to perform soldering.

Examples of the heating method include hot air reflow and infrared reflow. Furthermore, the heating method may be a method of heating the entirety or may be a method of locally heating. The heating temperature may be, for example, within a range of 240 to 280° C.

### EXAMPLES

Hereinafter, the present disclosure will be described in detail based on Examples; however, the present disclosure is not limited thereto.

### [Production of Film-Like Adhesive]

### Examples 1 to 5 and Comparative Examples 1 to 4

### <Preparation of Bonding Adhesive Varnish>

Cyclohexanone was added to a mixture composed of the component (A), the component (B), and the component (D) with the components and the contents (unit: parts by mass) shown in Table 1, and the mixture was stirred and mixed. The component (C) was added thereto with the components and the contents (unit: parts by mass) shown in Table 1 and stirred, the component (E) and the component (F) were further added, and the mixture was stirred until each component was uniform, thereby preparing a bonding adhesive varnish. Note that, respective components shown in Table 1 mean the following components, and numerical values shown in Table 1 mean mass parts of solid contents.

### Component (A): Epoxy Resin

(A-1)N-500P-10 (trade name, manufactured by DIC Corporation, o-cresol novolac type epoxy resin, epoxy equivalent: 203 g/eq)
(A-2) YDF-8170C (trade name, manufactured by Nippon Steel & Sumikin Chemical Co., Ltd., bisphenol F type epoxy resin, epoxy equivalent: 159 g/eq)

### Component (B): Phenolic Resin

(B-1) MEH-7800M (trade name, manufactured by Meiwa Plastic Industries. Ltd., phenol novolac type phenolic resin, hydroxyl equivalent: 175 g/eq, softening point: 61 to 90° C.)
(B-2) GPH-103 (trade name, manufactured by Nippon Kayaku Co., Ltd., biphenyl aralkyl type phenolic resin, hydroxyl equivalent: 230 g/eq, softening point: 99 to 106° C.)

### Component (C): Elastomer

(C1-1) Acrylic rubber solution (cyclohexanone solution of acrylic rubber, actual measured Tg of acrylic rubber: 20° C., weight average molecular weight of acrylic rubber: 800000)
(C1-2) Acrylic rubber solution (cyclohexanone solution of acrylic rubber, actual measured Tg of acrylic rubber: 12° C., weight average molecular weight of acrylic rubber: 300000)
(C1-3) Acrylic rubber solution (cyclohexanone solution of acrylic rubber, actual measured Tg of acrylic rubber: 12° C., weight average molecular weight of acrylic rubber: 800000)

### Component (D): Inorganic Filler

(D-1) Silica filler dispersion (manufactured by ADMATECHS COMPANY LIMITED, cyclohexanone dispersion of silica filler, average particle diameter: 180 nm)
(D-2) Silica filler dispersion (manufactured by ADMATECHS COMPANY LIMITED, cyclohexanone dispersion of silica filler, average particle diameter: 50 nm)

### Component (E): Coupling Agent

(E-1) A-189 (trade name, manufactured by Nippon Unicar Company Limited, γ-mercaptopropyltrimethoxysilane)

### Component (F): Curing Accelerator

(F-1) 2PZ-CN (trade name, manufactured by SHIKOKU CHEMICALS CORPORATION, 1-cyanoethyl-2-phenylimidazole)

### <Production of Film-Like Adhesive>

The prepared bonding adhesive varnish was filtered with a 500-mesh filter and vacuum-defoamed. A polyethylene terephthalate (PET) film having a thickness of 38 μm that had been subjected to a mold release treatment was prepared as a support film, and the vacuum-defoamed bonding adhesive varnish was applied onto the PET film. The applied bonding adhesive varnish was heated and dried in two stages at 90° C. for 5 minutes and then at 130° C. for 5 minutes to obtain film-like adhesives of Examples 1 to 5 and Comparative Examples 1 to 4 in a B-stage state. As the film-like adhesive, film-shaped adhesives having two types of thickness (10 μm and 20 μm) were prepared for each of Examples and Comparative Examples. The thickness of the film-like adhesive was adjusted by the coating amount of the bonding adhesive varnish.

### [Evaluation of Ease of Splitting by Cooling Expansion]

Each bonding adhesive piece (thickness: 10 μm, width 5 mm x length 100 mm) was cut out from the film-like adhesives (thickness: 10 μm) of Examples 1 to 5 and Comparative Examples 1 to 4. The bonding adhesive pieces were fixed by a pair of jigs (thick paper) and protruding portions of the bonding adhesive pieces from the jigs were removed. Thereby, evaluation target samples (width 5 mm x length 23 mm) were obtained. A break test was performed in a thermostat bath (manufactured by AETEC Co., Ltd., TLF-R3-F-W-PL-S) set to 0° C. That is, the break test was performed using an autograph (manufactured by A&D Company, Limited, AZT-CA01, load cell 50 N) in a compression mode under the conditions of a speed of 10 mm/min and a pushing distance of 5 mm, and the breaking work W, the breaking strength P, and the breaking elongation L when the film-like adhesive was broken were obtained. Furthermore, the breaking factor m and the breaking resistance R were calculated from the above-described Equation (1) and Equation (2). Note that, the breaking factor m and the breaking resistance R are the average values obtained by performing the break test 8 times or more for each Example and each Comparative Example. As the numerical value of the breaking factor m decreases, there is a tendency that the ease of splitting by cooling expansion is excellent. In a case where the breaking factor m is 70 or less, this case was excellent in the ease of splitting by cooling expansion and was evaluated as “A”, and a case where the breaking factor m is more than 70 was evaluated as “B”. Results are shown in Table 1.

### [Evaluation of Adhesion Maintainability at Time of High-Temperature Treatment]

### <Production of Integrated Dicing/Die Bonding Film>

First, the film-like adhesives (thickness: 20 μm) of each of Examples 1 to 5 and Comparative Examples 1 to 4, as well as a dicing film having a pressure-sensitive adhesive layer composed of an ultraviolet curable pressure-sensitive adhesive were prepared. Next, the film-like adhesive and the pressure-sensitive adhesive layer of the dicing film were pasted to produce each of integrated dicing/die bonding films of Examples 1 to 5 and Comparative Examples 1 to 4.

### <Production of Sample for Evaluation>

The adhesion maintainability at the time of a high-temperature treatment was evaluated using the integrated dicing/die bonding film produced above. A sample for evaluation for evaluating the adhesion maintainability at the time of a high-temperature treatment was produced as follows. A semiconductor wafer having a thickness of 75 μm was prepared, the film-like adhesive side of the integrated dicing/die bonding film was pasted to the semiconductor wafer at a stage temperature of 70° C., thereby producing a sample for dicing. The obtained sample for dicing was cut using a full auto dicer DFD-6361 (manufactured by DISCO Corporation). The cutting was performed by a step cutting manner using two blades, and dicing blades ZH05-SD2000-N1-70-FF and ZH05-SD4000-N1-70-EE (both manufactured by DISCO Corporation) were used. The cutting conditions were set such that the number of revolutions of the blade was 4000 rpm, the cutting speed was 50 mm/sec, and the chip size was 7.5 mm×7.5 mm. Regarding the cutting, the first cutting was performed so that about 200 μm of the semiconductor wafer remained, and the second cutting was performed so that about 20 μm of cuts were formed in the dicing film. Next, the pressure-sensitive adhesive layer composed of an ultraviolet curable pressure-sensitive adhesive was irradiated with ultraviolet rays to cure the pressure-sensitive adhesive layer, and the bonding adhesive piece-attached semiconductor element was picked up. Subsequently, the picked-up bonding adhesive piece-attached semiconductor element was press-bonded to a step portion of a support member (substrate) having a 6 μm step on the surface with a bonding adhesive piece interposed therebetween by using a die bonder (manufactured by Besi, Esec 2100 sD PPP Plus) under the conditions of a temperature of 120° C., a pressure of 0.1 MPa, and a time of 1.0 second, thereby producing a sample for evaluation.

### <Production of Package for Evaluation and Evaluation of Adhesion Maintainability at Time of High-Temperature Treatment>

At least four support members (substrates) of the samples for evaluation produced above were prepared for each integrated dicing/die bonding film, and these support members were disposed on a hot plate. The hot plate was heated to a temperature of 150° C. to obtain samples for evaluation with thermal histories of 3 hours, 4 hours, 5 hours, and 6 hours. Subsequently, each sample for evaluation was encapsulated by a sealing material for molding (manufactured by Showa Denko Materials Co., Ltd., trade name “CEL-9750ZHF10”) by using a molding machine (manufactured by APIC YAMADA CORPORATION), thereby obtaining a package for evaluation. Note that, the sealing conditions for the sealing material were set to 175° C./6.8 MPa/120 sec. Next, the package for evaluation was observed using an ultrasonic imaging device (SAT) to check for the presence or absence of peeling between the support member (substrate) and the bonding adhesive piece. In a case where peeling was not observed after heating at 150° C. for 6 hours, this case was excellent in adhesion maintainability at the time of a high-temperature treatment and was evaluated as “A”, and a case where peeling was observed after heating at 150° C. for shorter than 6 hours was evaluated as “B”. Results are shown in Table 1.

TABLE 1

| | | Comp. | Comp. | Comp. | Comp. | | | | | |
|---|---|---|---|---|---|---|---|---|---|---|
| | | Exam. 1 | Exam. 2 | Exam. 3 | Exam. 4 | Exam. 1 | Exam. 2 | Exam. 3 | Exam. 4 | Exam. 5 |
| (A) | (A-1) | 7.8 | 7.4 | 8.7 | 8.2 | 10.6 | 9.9 | 12.1 | 9.0 | 9.9 |
| | (A-2) | — | — | 0.7 | — | — | — | — | — | — |
| (B) | (B-1) | 3.5 | 3.3 | 4.2 | 6.9 | 4.5 | 4.2 | 2.9 | 5.1 | 4.2 |
| | (B-2) | 4.6 | 4.4 | 5.5 | — | — | — | — | — | — |
| (C) | (C1-1) | 67.7 | 64.5 | 60.5 | 64.5 | 64.5 | 60.5 | 64.5 | — | — |
| | (C1-2) | — | — | — | — | — | — | — | 30.2 | 30.2 |
| | (C1-3) | — | — | — | — | — | — | — | 30.2 | 30.2 |
| (D) | (D-1) | 16.0 | 20.0 | 20.0 | 20.0 | 20.0 | 25.0 | 20.0 | 25.0 | — |
| | (D-2) | — | — | — | — | — | — | — | — | 25.0 |
| (E) | (E-1) | 0.4 | 0.4 | 0.4 | 0.4 | 0.4 | 0.4 | 0.4 | 0.4 | 0.4 |
| (F) | (F-1) | 0.01 | 0.01 | 0.01 | 0.01 | 0.01 | 0.01 | 0.01 | 0.01 | 0.01 |

| | | | | | | | | | |
|---|---|---|---|---|---|---|---|---|---|
| Ratio of epoxy group of (A) | 1.0 | 1.0 | 1.0 | 1.0 | 2.0 | 2.0 | 3.5 | 1.5 | 2.0 |
| with respect to hydroxyl | | | | | | | | | |
| group of (B) | | | | | | | | | |
| Ease of cold splitting | A | A | A | A | A | A | A | A | A |
| Adhesion maintainability at | B | B | B | B | A | A | A | A | A |
| time of high-temperature | | | | | | | | | |
| treatment | | | | | | | | | |

As shown in Table 1, the film-like adhesives of Examples 1 to 5 were excellent in both of the ease of cold splitting and the adhesion maintainability at the time of a high-temperature treatment as compared to the film-like adhesives of Comparative Examples 1 to 4. From these results, it was confirmed that the film-like adhesive of the present disclosure is excellent in the ease of splitting by cooling expansion and can sufficiently maintain adhesiveness even at the time of a high-temperature treatment.

### REFERENCE SIGNS LIST

1: film-like adhesive, 1A: bonding adhesive layer, 2: base material layer, 3: pressure-sensitive adhesive layer, 4: dicing film, 10: integrated dicing/die bonding film, 11, 11a, 11b, 11c, 11d: semiconductor element, 12: support member, 13: wire, 14: sealing material, 15, 15a, 15b, 15c, 15d: bonding adhesive member, 16: terminal, 20: sample fixing jig, 20a: opening, 21: pushing jig, 21a: tip portion, 100, 110, 120: semiconductor device.

1. A film-like adhesive comprising an epoxy resin, a phenolic resin, an elastomer, and an inorganic filler, wherein
a ratio of an epoxy group of the epoxy resin with respect to a hydroxyl group of the phenolic resin is 1.2 or more.

2. The film-like adhesive according to claim 1, wherein the elastomer comprises an elastomer satisfying the following Condition (i) and the following Condition (ii):
Condition (i): a glass transition temperature is 10° C. or higher; and
Condition (ii): a weight average molecular weight is 1000000 or less.

3. The film-like adhesive according to claim 1, wherein a total content of the epoxy resin and the phenolic resin is 5 to 25% by mass based on the total amount of the film-like adhesive.

4. The film-like adhesive according to claim 1, wherein an average particle diameter of the inorganic filler is 400 nm or less.

5. The film-like adhesive according to claim 1, wherein a content of the inorganic filler is 18 to 40% by mass based on the total amount of the film-like adhesive.

6. The film-like adhesive according to claim 1, wherein a thickness is 25 μm or less.

7. The film-like adhesive according to claim 1, which is used in a production process of a semiconductor device obtained by stacking a plurality of semiconductor elements.

8. The film-like adhesive according to claim 7, wherein the semiconductor device is a three-dimensional NAND type memory.

9. A method for producing a film-like adhesive, the method comprising:
applying a varnish of a bonding adhesive composition comprising an epoxy resin, a phenolic resin, an elastomer, an inorganic filler, and a solvent to a support film; and
removing the solvent from the applied varnish by heating and drying to obtain a film-like adhesive, wherein
a ratio of an epoxy group of the epoxy resin with respect to a hydroxyl group of the phenolic resin is 1.2 or more.

10. An integrated dicing/die bonding film comprising a base material layer, a pressure-sensitive adhesive layer, and a bonding adhesive layer composed of the film-like adhesive according to claim 1 in this order.

11. A semiconductor device comprising:
a semiconductor element;
a support member on which the semiconductor element is mounted; and
a bonding adhesive member provided between the semiconductor element and the support member and bonding the semiconductor element and the support member, wherein the bonding adhesive member is a cured product of the film-like adhesive according to claim 1.

12. The semiconductor device according to claim 11, further comprising another semiconductor element stacked on the semiconductor element.

13. A method for producing a semiconductor device, the method comprising interposing the film-like adhesive according to claim 1 between a semiconductor element and a support member or between a first semiconductor element and a second semiconductor element, and bonding the semiconductor element and the support member or the first semiconductor element and the second semiconductor element.

14. A method for producing a semiconductor device, the method comprising:
pasting the bonding adhesive layer of the integrated dicing/die bonding film according to claim 10 to a semiconductor wafer;
dicing the semiconductor wafer to which the bonding adhesive layer is pasted;
expanding the base material layer under a cooling condition to produce a plurality of singulated bonding adhesive piece-attached semiconductor elements;
picking up the bonding adhesive piece-attached semiconductor element from the pressure-sensitive adhesive layer; and
bonding the picked-up bonding adhesive piece-attached semiconductor element to a support member with a bonding adhesive piece interposed therebetween.

15. The method for producing a semiconductor device according to claim 14, further comprising bonding the other bonding adhesive piece-attached semiconductor element to a surface of the semiconductor element bonded to the support member with a bonding adhesive piece interposed therebetween.
